(19) United States
(12) Patent Application Publication
(10) Pub. No.: US 2018/0083641 A1
(43) Pub. Date: Mar. 22, 2018

(54) Delay Locked Loop Including Plurality of Delay Lines

(71) Applicant: Samsung Electronics Co., Ltd., Suwon-si (KR)

(72) Inventors: Kyungho RYU, Suwon-si (KR); Dongmyung LEE, Hwaseong-si (KR); JaeYoul LEE, Hwaseong-si (KR); Kilhoon LEE, Seoul (KR); Jung-Pil LIM, Hwaseong-si (KR)

(21) Appl. No.: 15/650,263

(22) Filed: Jul. 14, 2017

(30) Foreign Application Priority Data
Sep. 19, 2016 (KR) 10-2016-0119399

(51) Int. Cl. H03L 7/081; H03L 7/087; H03L 7/07; H03K 5/05; H03K 5/24; G06F 1/10

(52) U.S. Cl. CPC H03L 7/0814; H03L 7/087; H03L 7/07; G06F 1/10; H03K 5/05; H03K 5/2481; H03L 7/0818

(57) ABSTRACT

A delay locked loop includes a first delay line and a second delay line. The first delay line is configured to generate a first delay clock, signal by passing an input clock, signal through a first number of logic gates among a plurality of logic gates and a second delay clock signal by passing the input clock signal through a second number of logic gates among the plurality of logic gates. The second delay line is configured to output an output clock signal based on one of a first signal having a first phase of the first delay clock signal, a second signal having a second phase of the second delay clock signal, and an interpolation signal having a third phase adjusted in stages by a reference value between the first phase and the second phase.

### CROSS-REFERENCE TO RELATED APPLICATIONS

This U.S. non-provisional patent application claims priority under 35 U.S.C. §119 of Korean Patent Application No. 10-2016-0119399, filed on Sep. 19, 2016, the entire contents of which arc hereby incorporated by reference.

### FIELD

The inventive concept relates to a delay locked loop, and, more particularly, to a delay locked loop including a plurality of delay lines.

### BACKGROUND

A semiconductor memory device capable of being mounted in a data processing device such as a personal computer, a notebook computer, or a portable electronic device, may include a delay locked loop.

A delay locked loop generates an internal clock signal, which is phase-synchronized to an external clock signal as an output clock signal using a delay line so that an operation of a semiconductor device is performed in synchronization with the external clock signal. That is, when a clock signal internally being used goes through a clock buffer and a transmission line of a semiconductor device, a timing delay may occur. To synchronize the internal clock signal with the external clock signal, the delay locked loop may adjust a phase of the internal clock signal.

### SUMMARY

Example embodiments of the inventive concept provide a delay locked loop. The delay locked loop includes a first delay line and a second delay line. The first delay line is configured to generate a first delay clock signal delayed by a first time as compared with an input clock signal by delaying the input clock signal through a plurality of logic gates and a second delay clock signal delayed by a second time as compared with the input clock signal by delaying the input clock signal through the plurality of logic gates and the second delay line is configured to output an output clock signal based on one of a first signal having a first phase of the first delay clock signal, a second signal having a second phase of the second delay clock signal, and an interpolation signal having a third phase between the first phase and the second phase.

The second delay line is further configured to transition from outputting the output dock signal based on the first signal to outputting the output clock signal based on the second signal by outputting the output clock signal based on the interpolation signal before outputting the output clock signal based on the second signal, and the third phase is adjusted in stages by a reference value from the first phase to the second phase while the second delay line outputs the output clock signal based on the interpolation signal.

Further example embodiments of the inventive concept provide a delay locked loop. The delay locked loop includes a first delay line and a second delay line. The first delay line is configured to generate a first delay clock signal by passing an input clock signal through a first number of logic gates among a plurality of logic gates; and a second delay clock signal by passing the input clock signal through a second number of logic gates among the plurality of logic gates.

The second delay line is configured to output an output clock signal based on one of a first signal having a first phase of the first delay clock signal, a second signal having a second phase of the second delay clock signal, and an interpolation signal having a third phase adjusted in stages by a reference value between the first phase and the second phase. The first number is different from the second number.

Still further example embodiments of the inventive concept provide a delay locked loop. The delay locked loop includes a first delay line configured to generate a first delay clock signal having a first phase and a second delay clock signal having a second phase responsive to an input clock signal, and a second delay line configured to generate an interpolation signal having a third phase based on the first and second delay clock signals, such that the third phase is sequentially incremented over a plurality of cycles of the input clock signal so as to span a phase range defined by the first phase and the second phase.

It is noted that aspects of the inventive concepts described with respect to one embodiment, may be incorporated in a different embodiment although not specifically described relative thereto. That is, all embodiments and/or features of any embodiment can be combined in any way and/or combination. These and other aspects of the inventive concepts are described in detail in the specification set forth below.

### BRIEF DESCRIPTION OF THE FIGURES

Embodiments of the inventive concept will be described below in more detail with reference to the accompanying drawings. The embodiments of the inventive concept may, however, be embodied in different forms and should not be constructed as limited to the embodiments set forth herein. Rather, these embodiments are provided so that this disclosure will be thorough and complete, and will fully convey the scope of the inventive concept to those skilled in the art. Like numbers refer to like elements throughout the description.

FIG. 1 is a block diagram illustrating a delay locked loop according to example embodiments of the inventive concept.

FIG. 2 is a table that illustrates a binary code and a thermometer code.

FIG. 3 is a circuit diagram illustrating a first delay line of FIG. 1.

FIG. 4 is a block diagram illustrating a second delay line of FIG. 1.

FIG. 5 is a circuit diagram illustrating a second delay line of FIG. 1.

FIG. 6 is a circuit diagram illustrating a method of delaying an input clock signal of a first delay line of FIG. 1.

FIG. 7 is a circuit diagram illustrating a method of outputting a final output clock signal from a second delay line of FIG. 1.

FIG. 8 is a timing diagram illustrating a final output clock signal, which is output from a second delay line of FIG. 7.

FIG. 9 is a circuit diagram illustrating a phase interpolation operation of a second delay line of FIG. 1.

FIGS. 10A and 10B are timing diagrams illustrating a final output clock signal, which is output from a second delay line of FIG. 9.

FIG. 11 is a circuit diagram illustrating a method in which a final output clock signal is output from a second delay line of FIG. 1.

FIGS. 12A and 12B are timing diagrams illustrating a final output clock signal, which is output from a second delay line of FIG. 11.

FIG. 13 is a circuit diagram illustrating a method of delaying an input clock signal of a first delay line of FIG. 1.

FIG. 14 is a block diagram illustrating a display system including a delay locked loop according to example embodiments of the inventive concept.

FIG. 15 is a block diagram illustrating a user system including a delay locked loop according to example embodiments of the inventive concept.

### DETAILED DESCRIPTION OF THE EMBODIMENTS

The inventive concept will now be described more fully with reference to the accompanying drawings, in which exemplary embodiments are shown. The inventive concept may, however, be embodied in many different forms without departing from the scope of the inventive concept or essential features. These embodiments are only for illustrative purposes and should not be construed as being limited to the embodiments set forth herein.

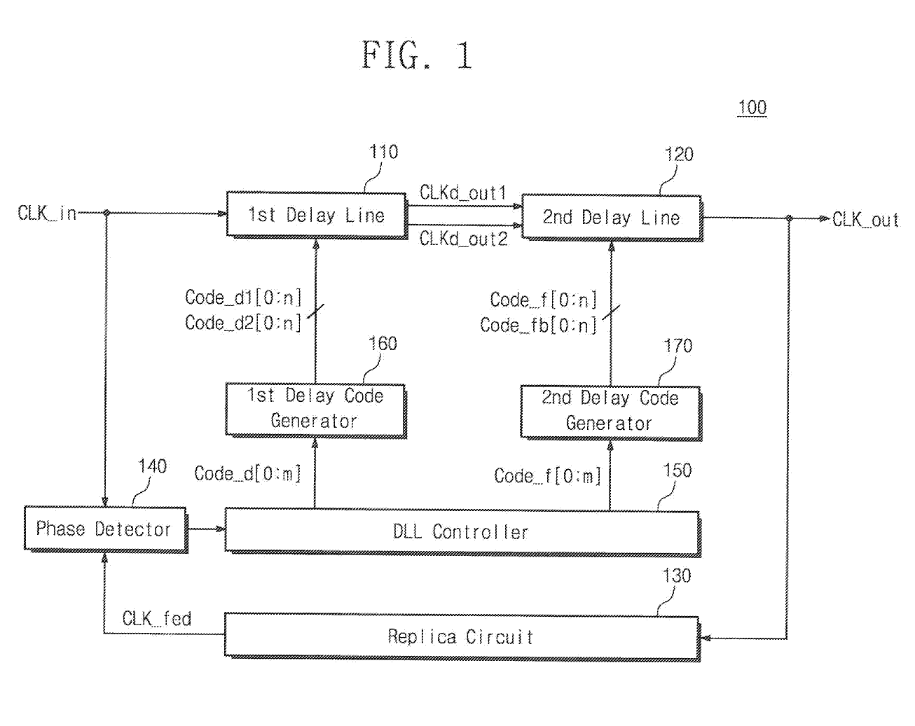

FIG. 1 is a block diagram illustrating a delay locked loop according to example embodiments of the inventive concept. Referring to FIG. 1, a delay locked loop 100 may include a first delay line 110, a second delay line 120, a delay replica circuit 130, a phase detector 140, a delay controller 150, a first delay code generator 160 and a second delay code generator 170.

The first delay line 110 may receive an input clock signal CLK_in. The first delay line 110 can delay the Input clock signal CLK in for a predetermined time. The first delay line 110 may receive first and second thermometer codes (Code_d1[0:n], Code_d2[0:n]) from the first delay code generator 160 and may delay the input clock signal CLK_in in response to the received first and second thermometer codes (Code_d1[0:n], Code_d2[0:n]). An operation for delaying the input clock signal CLK_in performed in the first delay line 110 may be called a coarse lock operation.

The first delay line 110 may comprise a plurality of delay circuits to delay the input clock signal CLK_in. The first delay line 110 can output delay clock signals (CLKd_out1, CLKd_out2) at the same time. The delay clock signals (CLKd_out1, CLKd_out2) may be generated by passing the input clock signal CLK_in through different numbers of delay circuits. As an example, the first delay clock signal CLKd_out1 may be obtained by delaying the input clock signal CLK_in for a first time. The second delay clock signal CLKd_out2 may be obtained by delaying the input clock signal CLK_in for a second time.

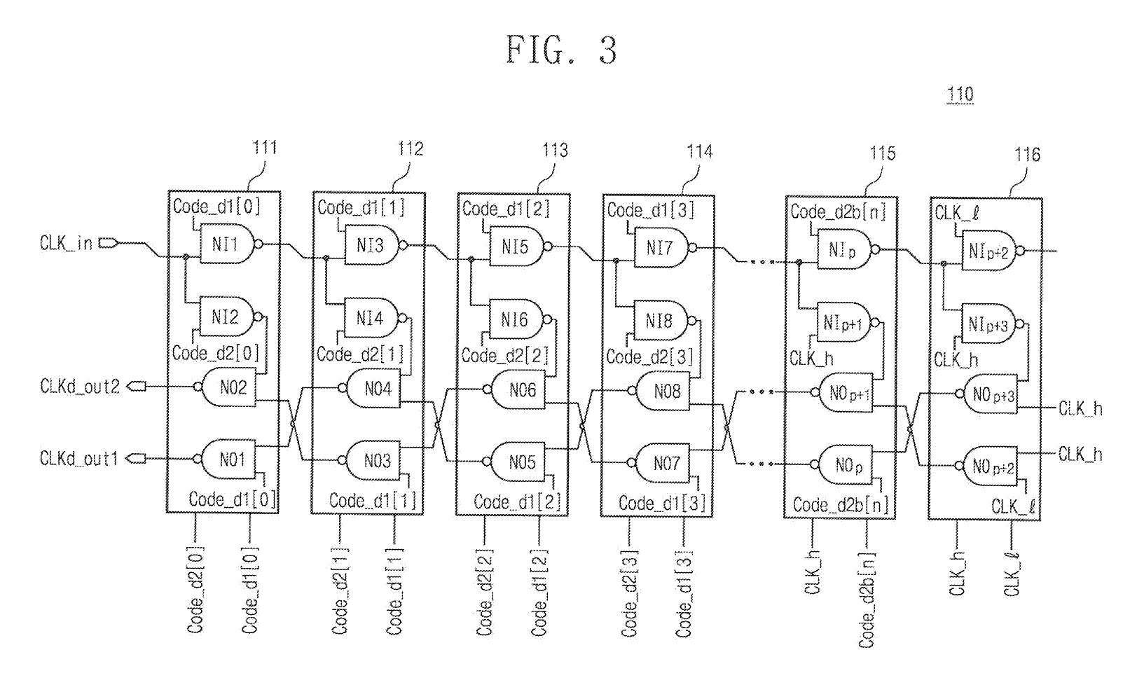

For example, each of the plurality of delay circuits may include a plurality of logical gates to adjust an amount of delay of each of the delay clock signals (CLKd_out1, CLKd_out2). A structure of the first delay line 110 and a method of operating the first delay line 110 are described in detail with reference to FIGS. 3, 5 and 9 according to some embodiments of the inventive concept.

The second delay line 120 may receive the delay clock signals (CLKd_out1, CLKd_out2) from the first delay line 110. The second delay line 120 may receive third and fourth thermometer codes (Code_f[0:n], Code_fb[0:n]) from the second delay code generator 170. The second delay line 120 may interpolate the delay clock signals (CLKd_out1, CLKd_out2) based on the received third and fourth thermometer codes (Code_f[0:n], Code_fb[0:n]).

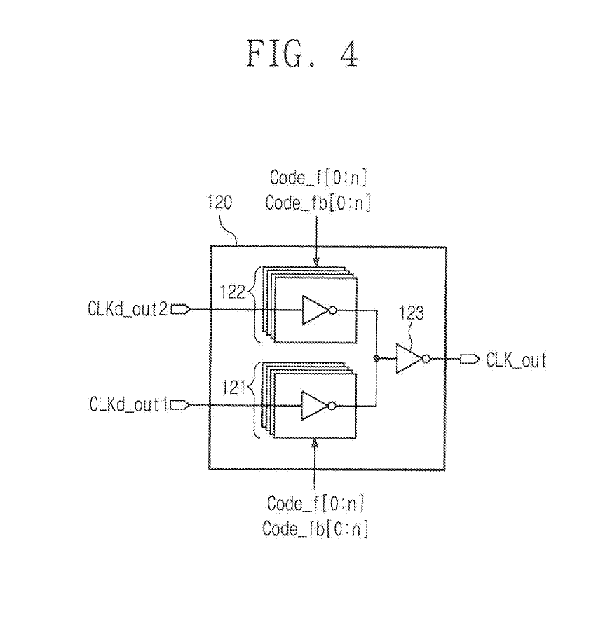

The second delay line 128 may interpolate a phase of the delay clock signals (CLKd_out1, CLKd_out2). The second delay line 120 may comprise a plurality of control circuits to interpolate a phase of the delay clock signals (CLKd_out1, CLKd_out2). The second delay line 120 may generate an output clock signal CLK_out based on the plurality of control circuits. For example, the second delay line 120 may change a phase of the output clock signal CLK_out from a phase of the first delay clock signal CLKd_out1 to a phase of the second delay clock signal CLKd_out2 over several cycles. A structure and an operation method of the second delay line 120 are described in detail with reference to FIGS. 4 and 5 through 7 according to some embodiments of the inventive concept.

The delay replica circuit 130 may receive the output clock signal CLK_out from the second delay line 120. The delay replica circuit 130 may delay the output clock signal CLK_out based on the delay generated by the delay locked loop 100. The delay replica, circuit 130 may be designed to compensate for a delay generated by delay devices that exist on a path to an output stage of a circuit. The delay replica circuit 130 may output the output clock signal CLK_out as a feedback clock signal CLK_fed.

The phase detector 140 may receive the input clock signal and the feedback clock signal CLK_fed. The phase detector 140 may compare a difference between a phase of the input clock signal and a phase of the feedback clock signal CLK_fed and may generate a phase detection signal as a comparison result. The phase detection signal may determine an increase or a decrease of an amount of delay of the first delay line 110. More specifically, the phase detection signal may be a code increasing signal for directing an increase of a code value generated by the delay controller 150 or a code decreasing signal for directing a decrease of the code value generated by the delay controller 150. The code increasing signal is a signal to increase an amount of delay of the first delay line 110 and the code decreasing signal is a signal to decrease an amount of delay of the first delay line 110.

The delay controller 150 may receive a phase detection signal from the phase detector 140. The delay controller 150 may control an increase or a decrease of an amount of delay of the first delay line 110 based on the phase detection signal. The delay controller 150 may output a first delay code (Code_d[0:m]) to control an amount of delay of the first delay line 110. The first delay code (Code_d[0:m]) may be a 4-bit binary code. The delay controller 150 may add a binary value of to the first delay code (Code_d[0:m]) or may subtract the binary value of ‘1’ from the first delay code (Code_d[0:m]). Values of each of the first delay code (Code_d[0:m]) bits may determine which of the delay circuits of the first delay line 110 is activated. This is merely an example for describing the inventive concept and a number of bits of the first delay code (Code_d[0:m]) is not limited to 4 bits.

The delay controller 150 may output a second delay code (Code_f[0:m]) to control an amount of delay of the second delay line 120. The delay controller 150 may adjust a bit value of the second delay code (Code_f[0:m]) based on first delay code (Code_d[0:m]). If an amount of delay of the first delay line 110 is adjusted based on bit values of first delay code (Code_d[0:m]), the delay controller 150 may add a binary value of ‘1’ to the second delay code (Code_f[0:m]) or may subtract the binary value of ‘1’ from the second delay code (Code_f[0:m]). This is merely an example for describing the inventive concept and a number of bits of the second delay code (Code_f[0:m]) is not limited to 4 bits.

The first delay code generator 160 may receive the first delay code (Code_d[0:m]) from the delay controller 150. The first delay code generator 160 may decode the received first delay code (Code_d[0:m]) to generate a thermometer code. The first delay code generator 160 may generate the first and second thermometer codes (Code_d1[0n], Code_d2[0:n]). The value range of each of the first and second thermometer codes (Code_d1[0:n], Code_d2[0:n]) depends on the number of bits of the first delay code (Code_d[0:m]). The value range of each of the first and second thermometer codes (Code_d1[0:n], Code_d2[0:n]) may be from 0 to 2ⁿ-1 (n is the number of bits of the first delay code (Code_d[0:m]). For example, in the case where the first delay code (Code_d[0:m]) has 4 bits, the value, range of each of the first and second thermometer codes (Code_d1[0:n], Code_d2[0:n]) may be from 0 to 15.

The second delay code generator 170 may receive the second delay code (Code_f[0:m]) from the delay controller 150. The second delay code generator 170 may decode the second delay code (Code_f[0:m]) to generate a thermometer code. The second delay code generator 170 may generate the third and fourth thermometer codes (Code_f[0:n], Code_fb[0:n]). The value range of each of the third and fourth thermometer codes (Code_f[0:n], Code_fo[0:n]) depends on the number of bits of the second delay code (Code_f[0:m]). The value range of each of the third and fourth thermometer codes (Code_f[0:n], Code_fb[0:n]) may be from 0 to 2ⁿ-1 (n is the number of bits of the second delay code (Code_f[0:m])).

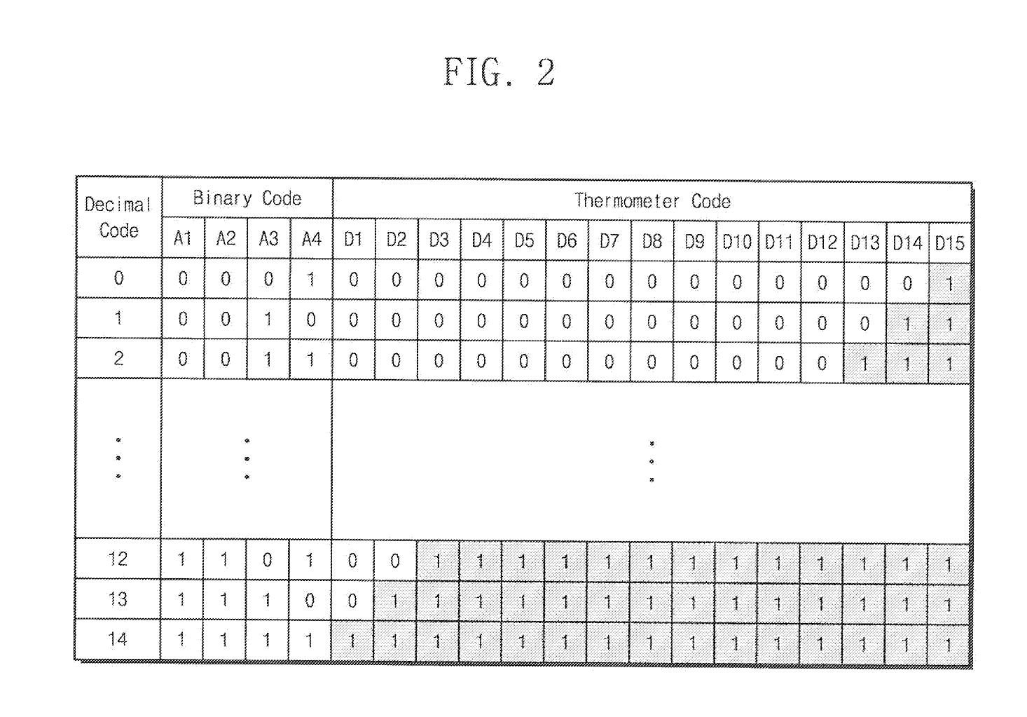

A relationship between the binary code and the thermometer code will be described in further detail with reference to FIG. 2. FIG. 2 is a table that illustrates a binary code and a thermometer code according to some embodiments of the inventive concept.

Referring to FIGS. 1 and 2, each of the first and second delay code generators 160 and 170 may generate thermometer codes (Code_d1[0:n], Code_d2[0:n], Code _f[0:n], Code_f[0:n]). As illustrated in FIG, 2, a 4-bit binary code (A1, A2, A3, A4) may be decoded to a thermometer code (D1 to D15) comprising 15 bits. The 4-bit binary code may increase from ‘0001’ to ‘1111’. The thermometer code (D1 to D15) may change the least significant bit which is not 1 into 1 in proportion to an increase of the binary code. For example, the thermometer code (D1 to D15) may increase from ‘000 . . . 001 to ‘111 . . . 111’,

In the case of changing an amount of delay of the output clock signal CLK_out, the output clock signal CLK_out is changed from the first delay clock signal CLKd_out1 to the second delay clock signal CLKd_out2.

However, the delay locked loop 100 may not change the output clock signal CLK_out from the first delay clock signal CLKd_out1 to the second delay clock signal CLKd_out2. More specifically, the first delay line 110 of the delay locked loop 100 may output the delay clock signals (CLKd_out1, CLKd_out2) having a different amount of delay based on the input clock signal CLK_in. The second delay line 120 interpolates phases of the delay clock signals (CLKd_out1, CLKd_out2). Through this method, the second delay line 120 may change an amount of delay of the output clock signal CLK_out over several cycles. Thus, the delay locked loop 100 may prevent or reduce a likelihood of a glitch that may be generated when an amount of delay of the output clock signal CLK_out is changed.

The delay locked loop 100 may be included in at least one of, but not limited to, a personal computer, a desktop computer, a laptop computer, a tablet computer, a digital camera, a camcorder, a smart phone, a mobile device, and a wearable device.

FIG. 3 is a circuit diagram illustrating a first delay line of FIG. 1 according to some embodiments of the inventive concept. Referring to FIGS. 1 and 3, the first delay line 110 may include a plurality of delay circuits 111 to 116. Each of the plurality of delay circuits 111 to 116 may include 4 NAND gates. The two delay circuits 115 and 116 may be dummy circuits. The two delay circuits 115 and 116 may be understood to have the same meaning as the dummy circuits. The two delay circuits 115 and 116 may exist to apply a signal necessary for nth delay circuit (not illustrated). The number of remaining delay circuits except for the, delay circuits 115 and 116 may be the same as the number of bits of each of the first and second thermometer codes (Code_d1[0:n], Code_d2[0:n]),

The plurality of delay circuits 111 to 116 may be activated or inactivated by the first and second thermometer codes (Code_d1[0:n], Code_d2[0:n]). If taking the first delay circuit 111 as an example, in the case where the first and second thermometer codes (Code_d1[0:m], Code_d2[0:n]) being applied to the first delay circuit 111 are ‘0’ and ‘1’ respectively, the first delay circuit 111 is activated. In contrast, in the case where the first and second thermometer codes (Code_d1[0:n], Code_d2[0:n]) being applied to the first delay circuit 111 are ‘1’ and ‘0’ respectively, the first delay circuit 111 is inactivated.

The dummy circuits 115 and 116 may he always in an activation state. Thus, a first clock signal CLK_h and a code (Code_d2b[n]) may be applied to the first dummy circuit 115. The code (Code_d2b[n]) has an opposite value to the second thermometer code (Code_d2[n]) applied to an nth delay circuit (not illustrated). The first clock signal (CLK_h and a second clock signal CLK_l may be applied to the second dummy circuit 116. A value of the first clock signal CLK_h is always ‘1’ and a value of the second clock signal CLK_l is always ‘0’. The remaining delay circuits except for the dummy circuits 115 and 116 may be activated or inactivated in the same manner as the first delay circuit 111.

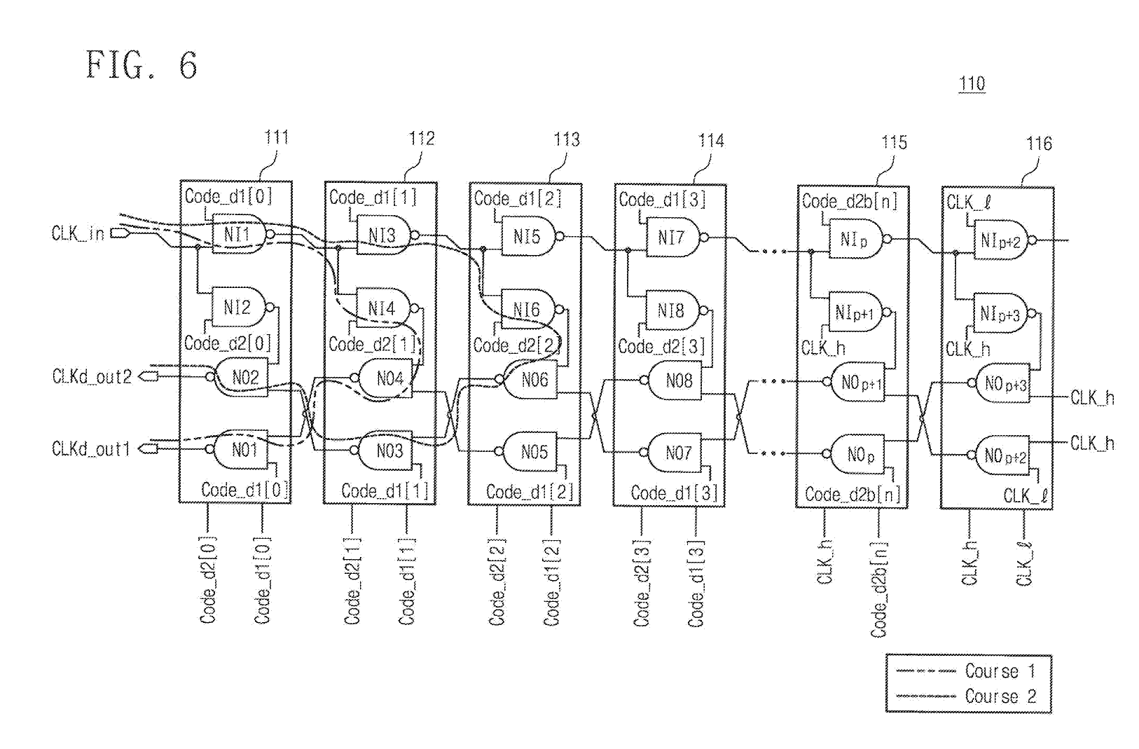

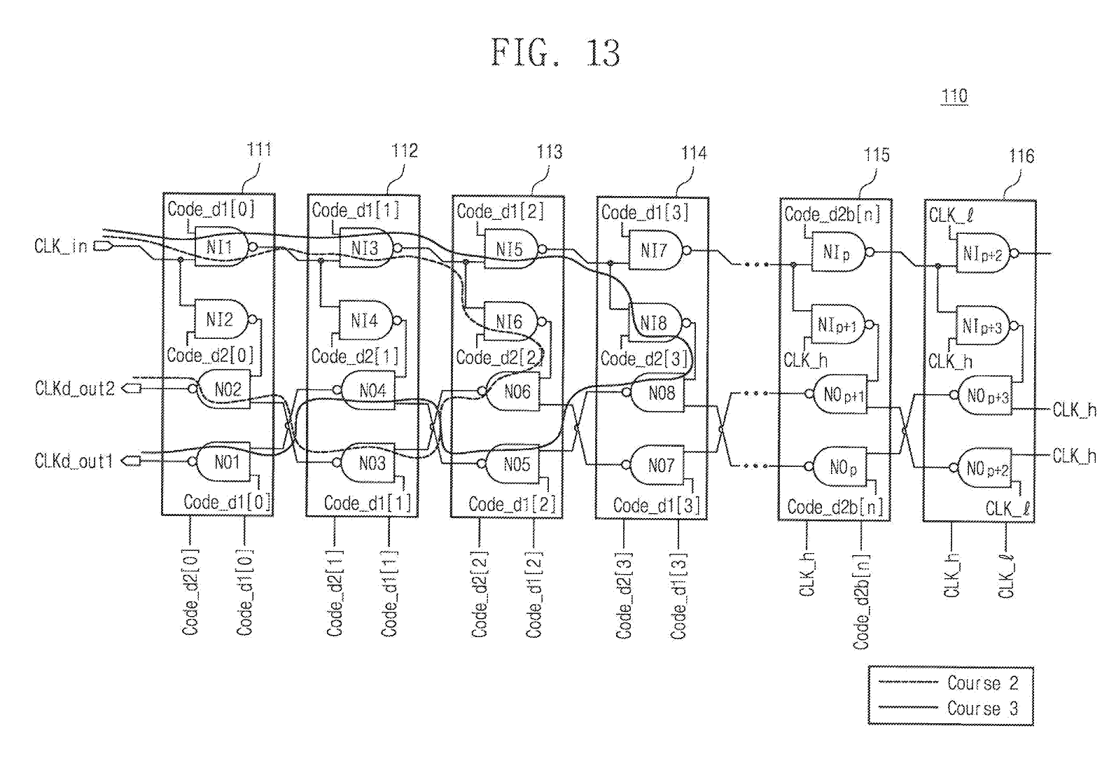

The input clock signal CLK_in may be received by first and second NAND gates NI1, NI2. The input clock signal CLK_in may go through a delay circuit being activated and may be output as the first delay clock signal CLKd_out1 or the second delay clock signal CLKd_out2. The input clock signal CLK_in may be delayed in proportion to the number of delay circuits through which the input clock signal CLK_in traverses. A method of generating the first delay clock signal CLKd_out1 or the second delay clock signal CLKd_out2 of the first delay line 110, according to some embodiments of the inventive concept, will be described in detail with reference to FIGS. 6 and 13.

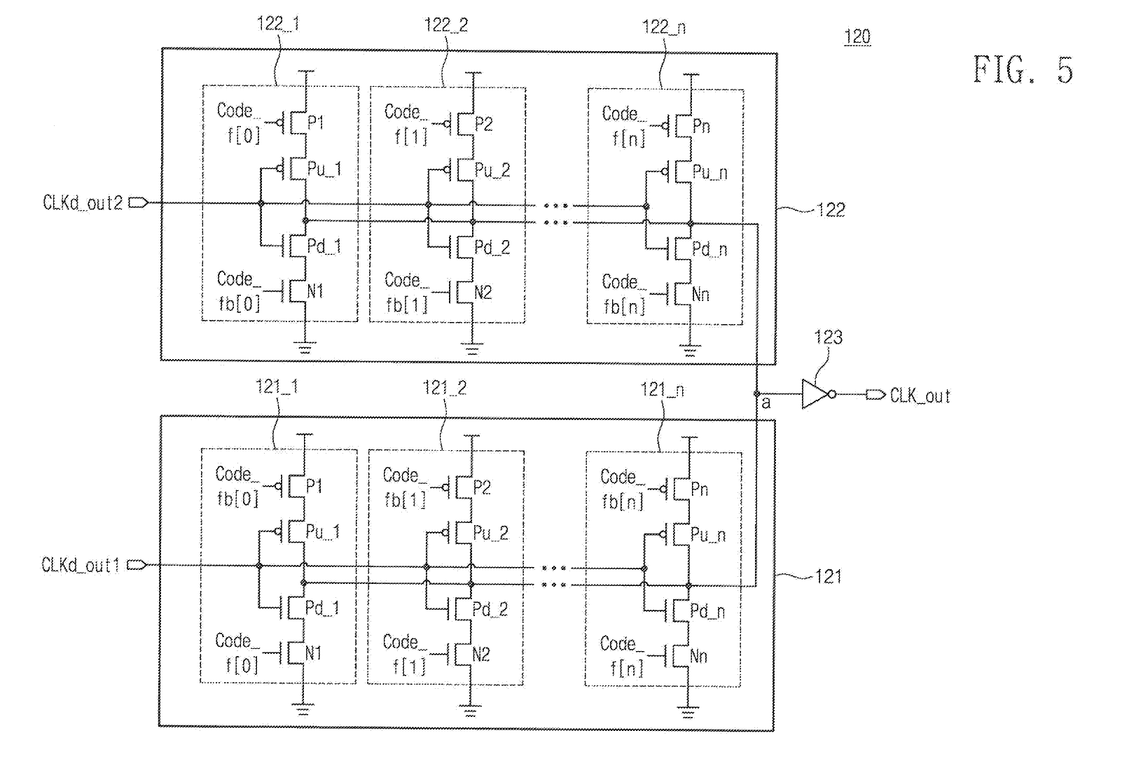

FIG. 4 is a block diagram illustrating a second delay line of FIG. 1 according to some embodiments of the inventive concept. FIG. 5 is a circuit diagram illustrating a second delay line of FIG. 1 according to some embodiments of the inventive concept. Referring to FIGS. 1 and 4, the second delay line 120 may include a first control circuit 121 and a second control circuit 122.

Each of the first and second control circuits 121 and 122 may receive third and fourth thermometer codes (Code_f[0:n], Code_fb[0:n]). Each of the first and second control circuits 121 and 122 may include a plurality of control cells. The first control circuit 121 may receive the first delay clock signal CLKd_out1 and the second control circuit 122 may receive the second delay clock signal CLKd_out2. Each of the first and second control circuits 121 and 122 may interpolation-control a phase of the first and second delay clock signals (CLKd_out1. CLKd_out2) based on the third and fourth thermometer codes (Code_f[0:n], Code_fb[0:n]),

FIG. 5 illustrates an internal circuit of the second delay line 120 according to some embodiments of the inventive concept. Referring to FIG. 5, the first control circuit 121 may include a plurality of control cells 121_1 to 121_n. The plurality of control cells 121_1 to 121_n of the first control circuit 121 may be connected in parallel with an output node (a). The second control circuit 122 may include a plurality of control cells 122_1 to 122_n. The plurality of control cells 122_1 to 122_n of the second control circuit 122 may be connected in parallel with an output node (a).

The number of each of the control cells 121_1 to 121_n of first control circuit 121 and the control cells 122_1 to 122_n of the second control circuit 122 may be the same as the number of bits of each of the third and fourth thermometer codes (Code_f[0:n], Code_fb[0:n]).

According to embodiments of the inventive concept, the first control cell 1211 of the first control circuit 121 is described by way of example. The first control cell 1211 may include a first pull-up transistor Pu_1 and a first pull-down transistor Pd_1. One end of the first pull-up transistor Pu_1 and one end of the first pull-down transistor Pd_1 may be connected to each other. The first pull-up transistor Pu_1 may be a PMOS transistor and the first pull-down transistor Pd_1 may be an NMOS transistor.

The first delay, clock signal CLKd_out1 may be received to a gate terminal of each of the first pull-up transistor Pu_1 and the first pull-down transistor. Pd_1. In the case where the first delay clock signal CLKd_out1 is ‘0’, the first pull-up transistor Pu_1 may be turned on and the first pull-down transistor Pd_1 may be turned off. In the case where the first delay clock signal CLKd_out1 is the first pull-up transistor Pu_1 may be turned off and the first pull-down transistor Pd_1 may be turned on.

The other end of the first pull-up transistor Pu_1 may be connected to one end of a first PMOS transistor P1. The other end of the first pull-down transistor may be connected to one end of a first NMOS transistor N1. A power supply voltage VDD may be applied to the other end of the first PMOS transistor P1 and the other end of the NMOS transistor N1 may be connected to earth ground or a common reference potential.

The third thermometer code Code_f[0] may be received at a gate terminal of the first PMOS transistor P1 and the fourth thermometer code Code_fb[0] may be received at a gate terminal of the first NMOS transistor N1. A phase of the third thermometer code Code_f[0] and a phase of the fourth thermometer code Code_fb[0] may be inverted relative to each other. For example, in the case where the third thermometer code Code_f[0] is ‘0’, the fourth thermometer code Code_fb[0] may be ‘1’ and in the case where the third thermometer code Code_f[0] is the fourth thermometer code Code_fb[0] may be ‘0’.

The first PMOS transistor P1 and the first NMOS transistor N1 may determine whether the first control circuit 121 is activated. Assuming that the first delay clock signal CLKd_out1 is ‘1’, in the case where the third thermometer code Code_f[0] is ‘0’ and the fourth thermometer code Code_fb[0] is ‘1’, the first control cell 121_1 may be activated. In the case where the first control cell 121_1 is activated, the output node (a) may be pulled down by a ground terminal. In this case, the amplitude of a signal of the output node (a) may be ‘0’.

The second through nth control cells 121_2 to 121_n of the first control circuit 121 may include a structure similar to or the same as the first control cell 121_1. Each of the control cells 121_1 to 121_n may be activated or inactivated in response, to the third thermometer code Code_f[0] and the fourth thermometer code Code_fb[0].

The second control circuit 122 may include a plurality of control cells 122_1 to 122_n. The control cells 122_1 to 122_n may be similar to or the same as the control cells 121_1 to 121_n respectively. However, PMOS transistors P1 to Pn and NMOS transistors N1 to Nn of the second control circuit 122 may operate in complementary fashion relative to the RMS transistors P1 to Pn and the NMOS transistors N1 to Nn of the first control circuit 121. More specifically, the fourth thermometer code Code_fb[0:n] is provided to a gate terminal of each of the POS transistors P1 to Pn of the second control circuit 122 and the third thermometer code Code_f[0:n] is provided to a gate terminal of each of the NMOS transistors N1 to Nn of the second control circuit 122.

Control cells of the second control circuit 122 may be inactivated, which correspond to the control cells being activated of the first control circuit 121. Because the first and second control circuits 121 and 122 complementarily operate relative to each other, the second delay line 120 may interpolate a phase of the first and second delay clock signals (CLKd_out1, CLKd_out2) by using a signal generated through the first control circuit 121 and a signal generated through the second control circuit 122. The second delay line 120 may output the output clock signal by interpolating the phase of the first and second delay clock signals (CLKd_out1, CLKd_out2).

An inverter 123 may be connected to the output node (a). The inverter 123 may receive a signal generated through the first control circuit 121, a signal generated through the second control circuit 122, or a signal generated through the first and second control circuits 121 and 122. The inverter 123 may invert the received signal to output the inverted signal as the output clock signal CLK_out.

FIG. 6 is a circuit diagram illustrating a method of delaying an input clock signal of a first delay line of FIG. 1 according to some embodiments of the inventive concept. Referring to FIGS. 1, 3 and 6, the first through third delay circuits 111 to 113 may be activated. When the first through third delay circuits 111 to 113 are activated, the input clock signal CLK_in may be output as the first delay clock signal CLKd_out1 and the second delay clock signal CLKd_out2 through a first course Course 1 and a second course Course 2. The first course Course 1 may be illustrated by a two-dot chain line and the second course Course 2 may be illustrated by a dotted line.

The first delay line 110 may operate only when the input clock signal CLK_in is ‘1’. When the input clock signal CLK_in is ‘0’, the first delay line 110 may not generate a delay clock signal. It is assumed that the input clock signal CLK_in is ‘1’.

The first course Course 1 may be formed through the first and second delay circuits 111 and 112. More specifically, the first course Course 1 may be formed through a first input NAND gate NI1, a fourth input NAND gate NI4, a fourth output NAND gate NO4, and a first output NAND gate NO1. The input clock signal CLK_in may be delayed by as much as the time (for example, delayed by as much as a first time) taken for the input clock signal CLK_in to pass through the first course Course 1. The input clock signal CLK_in delayed by as much as the first time may be output as the first delay clock signal CLKd_out1.

The second course Course 2 may be formed through the first through third delay circuits 111 to 113. More specifically, the second course Course 2 may be formed through the first input NAND gate the third input NAND gate NI3, a sixth input NAND gate NI6, a sixth output NAND gate NO6, a third output NAND gate NO3, and a second output NAND gate NO2. The input clock signal CLK_in may be delayed by as much as the time (for example, delayed by as much as a second time) taken for the input clock signal CLK_in to pass through the second course Course 2. The input clock signal CLK_in delayed by as much as the second time may be output as the second delay clock signal CLKd_out2.

The first delay clock signal CLKd_out1 may be generated through an even number of delay circuits. The second delay clock signal CLKd_out2 may be generated through an odd number of delay circuits.

For the input clock signal to be generated as the second delay clock signal CLKd_out2, the input clock signal CLK_in may pass through two NAND gates more as compared with when the input clock signal CLK_in is output as the first delay clock signal CLKd_out1. Accordingly, the second time is a time further delayed by as much as the time it takes for the input clock signal CLK_in to pass through two NAND gates as compared with the first tune.

In the case where the second delay clock signal CLKd_out2 is output as an output dock signal CLK_out immediately after the first delay clock signal CLKd_out1 is output as the output clock signal CLK_out, a glitch may be generated due to a delay difference between the first and second delay clock signals (CLKd _out1, CLKd_out2). When the glitch is generated, errors such as an incorrect operation, an output of invalid data, a system collision, etc. may occur in a device including the delay locked loop 100. The second delay line 120 may be provided to prevent or reduce the likelihood of an occurrence of a glitch that causes the errors.

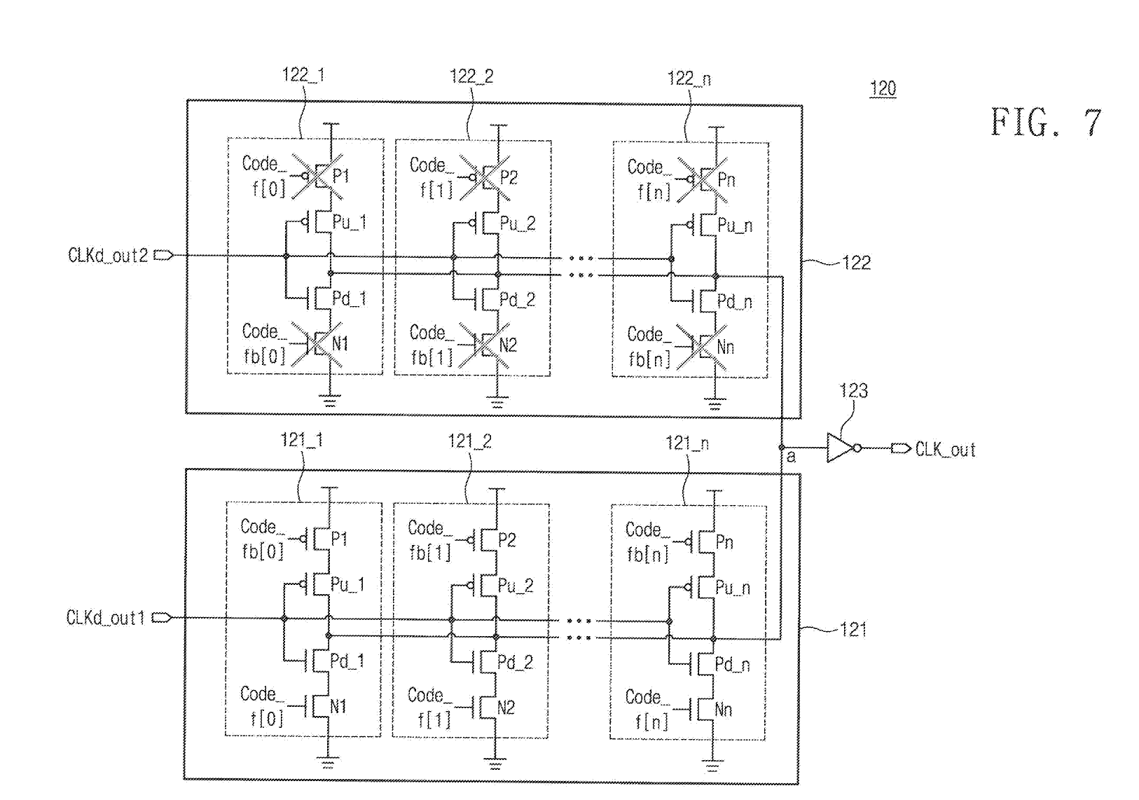

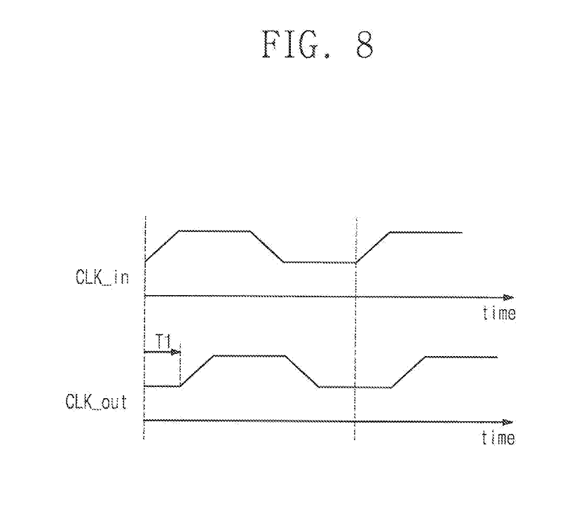

FIG. 7 is a circuit diagram illustrating a method of outputting a final output clock signal from a second delay line of FIG. 1 according to some embodiments of the inventive concept. FIG. 8 is a timing diagram illustrating a final output clock signal, which is output from a second delay line of FIG. 7 according to some embodiments of the inventive concept. FIG. 7 illustrates a method of operating the second delay line 120 when an output clock signal CLK_out is generated based on a phase of the first delay clock signal CLKd_out1.

Referring to FIGS. 1, 5 and 7, the control cells 121_1 to 121_n of the first control circuit 121 may all be activated. More specifically, the PMOS transistors P1 to Pn and the NMOS transistors N1 to Nn included in the control cells 121_1 to 121_n may be all turned on. The first delay clock signal CLKd_out1 can turn off the pull-up transistors Pu_1 to Pu_n included in the control, cells 121_1 to 121_n and can turn on the pull down transistors Pd_1 to Pd_n included in the control cells 121_1 to 121_n.

A signal generated through all the control cells 121_1 to 121_n of the first control circuit 121 may be transmitted to the output node (a). A signal generated through the first control circuit 121 may be inverted through the inverter 123. The inverted signal may be output as an output clock signal CLK_out.

Because the control cells 121_1 to 121_n of the first control circuit 121 and the control cells 122_1 to 122_n of the second control circuit 122 complementarily operate with respect to one another, the PMOS transistors P1 to Pn and the NMOS transistors N1 to Nn of the second control circuit 122 may be turned off. Thus, the control cells 122_1 to 122_n of the second control circuit 122 may be inactivated.

FIG. 8 illustrates a timing diagram of the input clock signal CLK_in and a timing diagram of the output clock signal CLK_out. Referring to FIGS. 6 through 8, an output clock signal CLK_out based on the input clock signal CLK_in may be generated through the first delay line 110 and the second delay line 120. The output clock signal CLK_out may be a signal delayed by as much as a first time T1 as compared with the input clock signal CLK_in. An amount (first time T1) of delay of the output clock signal CLK_put may be similar to or the same as an amount of delay of the first delay clock signal CLKd_out1.

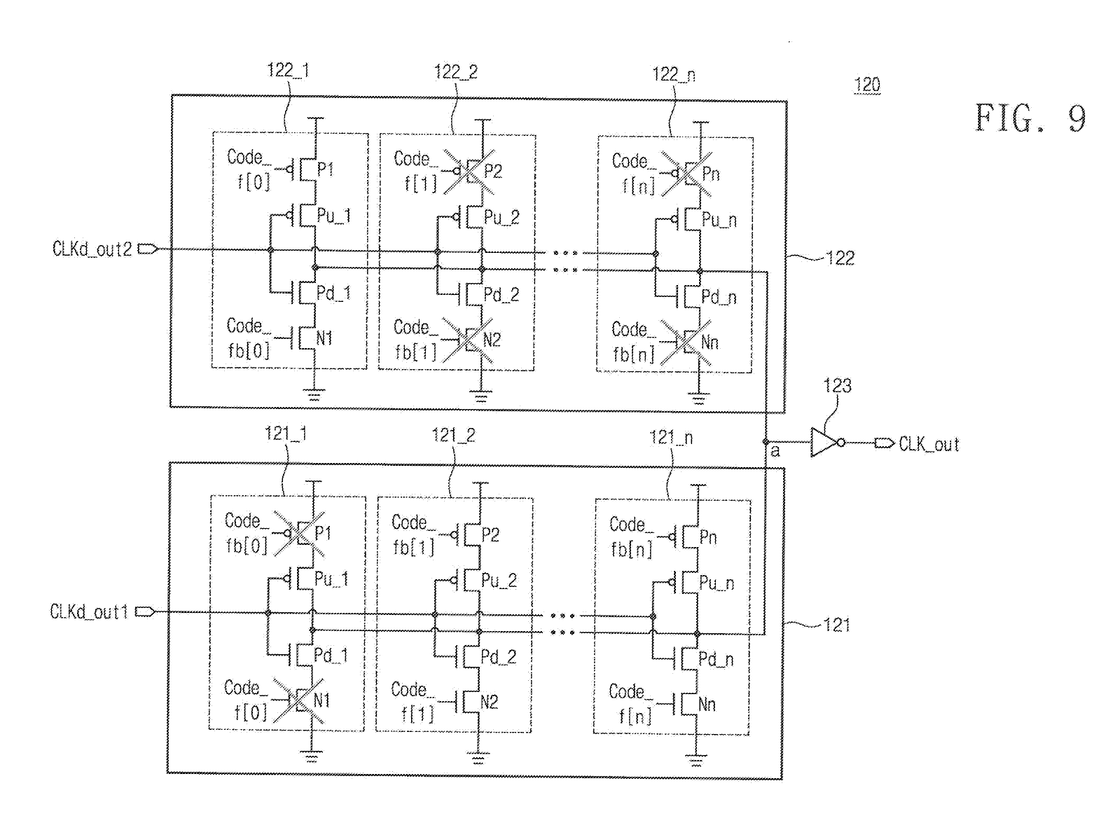

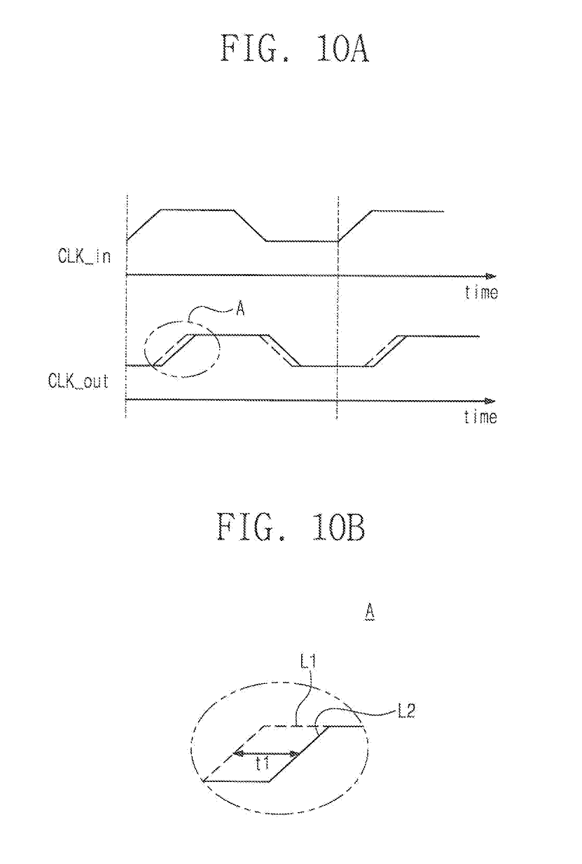

FIG. 9 is a circuit diagram illustrating a phase interpolation operation of a second delay line of FIG. 1 according to some embodiments of the inventive concept. FIGS. 10A and 10B are timing diagrams illustrating a final output clock signal, which is output from a second delay line of FIG. 9 according to some embodiments of the inventive concept. Referring to FIGS. 1 and 9, the delay locked loop 100 may adjust an amount of delay of the output clock signal CLK_out over several cycles.

In the delay locked loop 100, in the case where an output clock CLK_out generated based on the first delay clock signal CLKd_out1 is changed to an output clock CLK_out generated based on the second delay clock signal CLKd_out2, the second delay line 120 may interpolate a phase of the first and second delay clock signals (CLKd_out1, CLKd_out2) to adjust an amount of delay of the output clock signal CLK_out.

Referring to the second delay line 120 of FIG. 9, the first control cell 121_1 of the first control circuit 121 may be inactivated. The remaining control cells 121_2 to 121_n of the first control circuit 121 may remain in an activation state. A signal generated through the control cells 121_2, to 121_n may be transmitted to the output node (a).

The first control cell 122_1 of the second control circuit 122 may be activated. The remaining control cells 122_2 to 122_n of the second control circuit 122 may remain in an inactivation state. A signal generated through the first control cell 122_1 may be transmitted to the output node (a).

A phase of signals transmitted from the first control circuit 121 and the second control circuit 122 to the output node (a) may be interpolated. The signal transmitted to the output node (a) of FIG. 9 may be further delayed as compared with the signal transmitted to the output node (a) of FIG. 7. An amount of delay may be in proportion to a difference between a phase of the signal transmitted, to the output node (a) of FIG. 9 and a phase of the signal transmitted to the output node (a) of FIG. 7.

Referring to FIG. 9, the signal transmitted to the output node (a) may be inverted by the inverter 123 to be output as the output clock signal CLK_out. More specifically, the output clock signal CLK_out may be delayed in proportion to the interpolated phase.

Referring to FIGS. 9 and 10A, the output clock signal CLK_out is further delayed, as compared with the input clock signal CLK_in. The output clock signal CLK_out may be delayed based on an interpolation operation of the second delay line 120. The output clock signal CLK_out delayed in proportion to the interpolated phase is described with reference to part (A) of the timing diagram of the output clock signal CLK_out.

FIG. 10B illustrates part (A) of the timing diagram of the output clock signal CLK_out, in detail. Referring to FIG. 10B, a first line L1 may indicate an output clock signal CLK_out being output based on a signal generated through the first control circuit 121. A second line L2 may indicate an output clock signal CLK_out being output based on a signal generated through the first control circuit 121 and the second control circuit 122.

The output clock signal CLK_out illustrated by the second line L2 is a signal further delayed by as much as a first interpolation time t1 as compared with the output clock signal CLK_out illustrated by the first line L1. In this case, the first interpolation time t1 may be in proportion to a difference between a phase of a signal generated through the first control circuit 121 and a phase of a signal generated through the second control circuit 122.

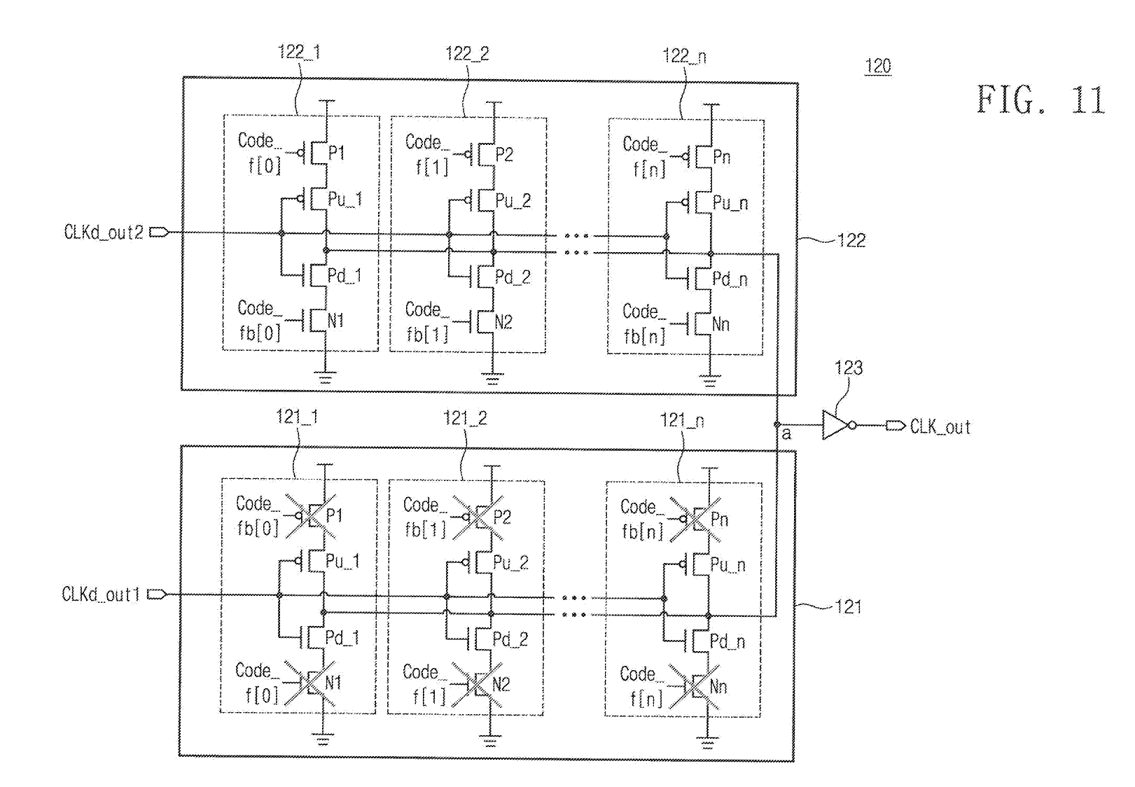

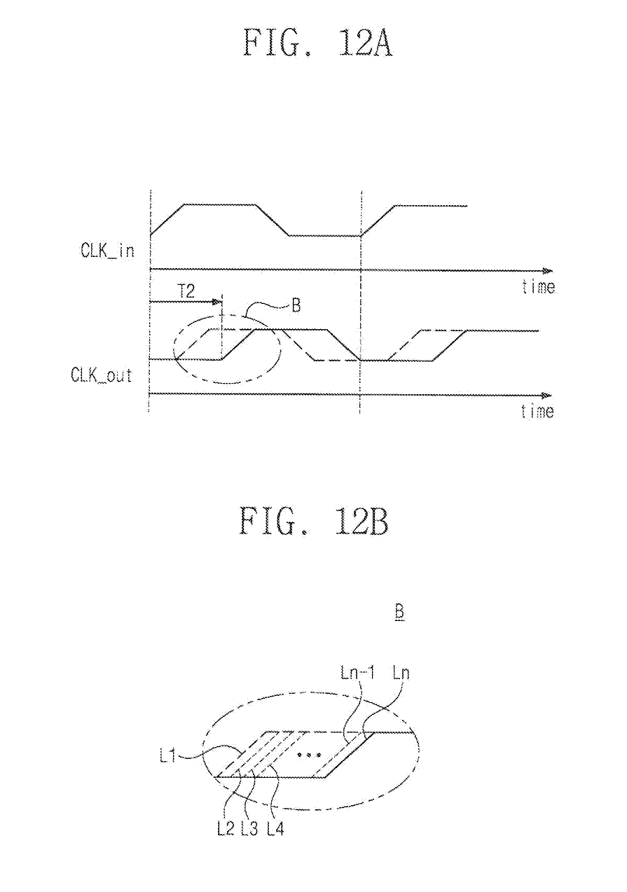

Referring to FIGS. 9, 10A and 10B, the second delay line 120 may adjust the number of the control cells 121_1 to 121_n, 122_1 to 122_n being activated or inactivated to change an amount of delay of the output clock signal CLK_out. More specifically, the control cells 121_1 to 121_n of the first control cell 121 may be inactivated one by one and the control cells 122_1 to 122_n of the second control cell 122 may be activated one by one. An operation of the second delay line 120 will be further described with reference to FIGS. 11 and 12 according to some embodiments of the inventive concept.

FIG. 11 is a circuit diagram illustrating a method in which a final output clock, signal is output from a second delay line of FIG. 1 according to some embodiments of the inventive concept. FIGS. 12A and 12B are timing diagrams illustrating a final output clock signal, which is output from a second delay line of FIG. 11 according to some embodiments of the inventive concept.

Referring to FIGS. 9 and 11, the control cells 121_1 to 121_n of the first control circuit 121 may be inactivated and the control cells 122_1 to 122_n of the second control circuit 122 may be activated. Because of this, a signal generated through the control cells 122_1 to 122₂n of the second control circuit 122 may be transmitted to the output node (a). The signal generated through the second control circuit 122 may be inverted through the inverter 123. The inverted signal may be output as an output clock signal CLK_out.

The control cells 121_1 to 121_n of the first control circuit 121 and the control cells 122_1 to 122₂n of the second control circuit 122 complementarily operate with respect to one another. Thus, for the second control circuit 122 to be activated, the PMOS transistors P1 to Pn and the NMOS transistors N1 to Nn of the second control circuit 122 may be turned on. For the first control circuit 121 to be inactivated, the PMOS transistors P1 to Pn and the NMOS transistors N1 to Nn of the first control circuit 121 may be turned off.

Referring to FIG. 12A, the output clock signal CLK_out, which is output through the second delay line 120 illustrated in FIG. 11, is a signal delayed by as much as a second time T2 as compared with the input clock signal CLK_in. A process of a delay of the output clock signal CLK_out is described based on part (B) of the timing diagram of the output clock signal CLK_out.

FIG. 12B illustrates part (B) of the timing diagram of the output clock signal CLK_out in detail. Referring to FIG. 12B, the output clock signal CLK_out may be delayed from a first line L1 to an nth line Ln. An interval between each of the first through nth lines L1 to Ln may mean an amount of delay between each of the output clock signals CLK_out. As illustrated in FIG. 10B, the interval between each of the first through nth lines L1 to Ln may be equal to the first interpolation time (t1).

When changing an amount of delay of the output clock signal CLK_out from a first time T1 to a second time T2, the probability that a glitch occurs may become high. When adjusting an amount of delay of the output clock signal CLK_out over several cycles by using the second delay line 120, the likelihood of a glitch may be reduced or prevented.

FIG. 13 is a circuit diagram illustrating a method of delaying an input clock signal of a first delay line of FIG. 1 according to some embodiments of the inventive concept. Referring to FIGS. 1, 6, 11 and 13, when the first control circuit 121 of the second delay line 120 becomes inactivated, the number of delay circuits selected in the first delay line 110 may be changed.

The first through fourth delay circuits 111 to 114 of the first delay line 110 may be selected. The second course Course 2 formed through the first through third delay circuits 111 to 113 may be maintained. Because the second course Course 2 was described with reference to FIG. 6, a detailed description is omitted.

As the fourth delay circuit 114 is additionally selected, a third course Course 3 may be formed along the first through fourth delay circuits 111 to 114. More specifically, the third course Course 3 may be formed through the first input NAND gate NI1, the third input NAND gate NI3, a fifth input NAND gate NI5, an eighth input NAND gate NI8, an eighth output NAND gate NO8, a fifth output NAND gate NO5, a fourth output NAND gate NO4, and a first output NAND gate NO1. The third course Course 3 may be illustrated by a solid line.

The input clock signal in may be delayed by as much as the time (for example, a third time) taken for the input clock signal CLK_in to pass through the third course Course 3. The input clock signal delayed by as much as the third time may be output as the first delay clock signal CLKd_out1.

The first delay clock signal CLKd_out1 is generated through two more NAND gates as compared with the second delay clock signal CLKd_out2. Because of this, the first delay clock signal CLKd_out1 may be further delayed by as much as the time it takes for the first delay clock signal CLKd_out1 to pass through the two NAND gates.

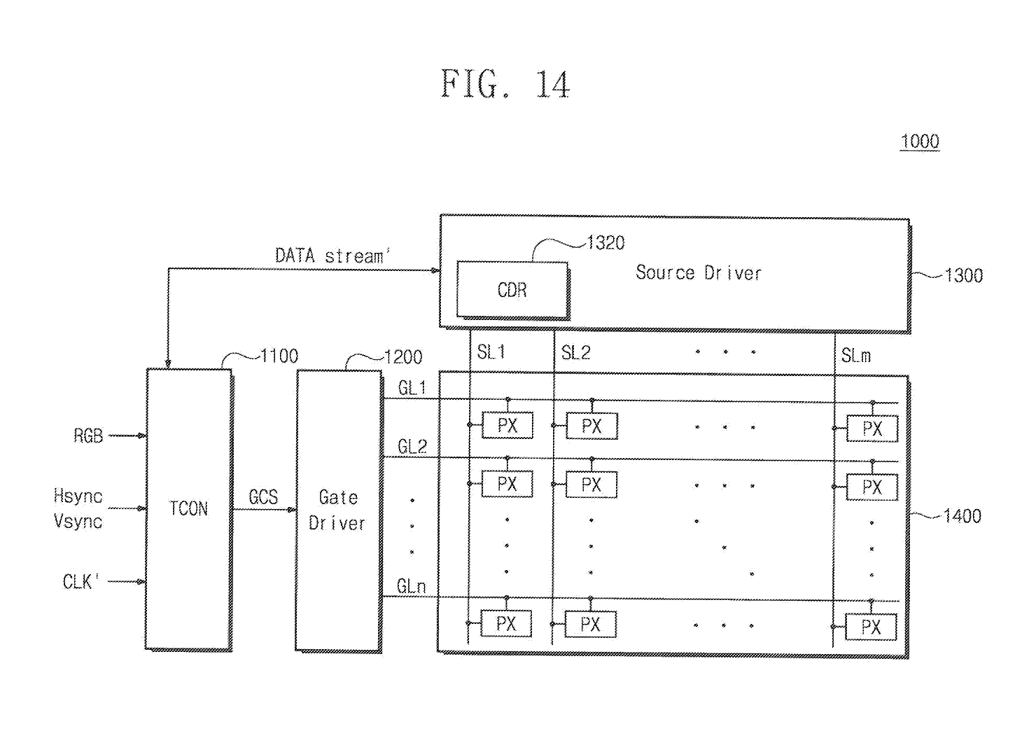

FIG. 14 is a block diagram illustrating a display system including a delay locked loop 100 according to example embodiments of the inventive concept. Referring to FIGS. 1 and 14, a display device 1000 may include a timing controller 1100, a gate driver 1200, a source driver 1300, and a display panel 1400.

The timing controller 1100 may receive image information RGB and a control signal from the outside. For example, the control signal may include a vertical synchronous signal Vsync, a horizontal synchronous signal Hsync, an external clock CLK′, etc. The timing controller 1100 may generate a serialized data stream DATA stream' and then may transmit the generated data stream DATA stream' to the source driver 1300 by changing a format of the image information RGB to meet specifications of the source driver 1300.

The timing controller 1100 may generate a gate control signal GCS based on a control signal (e.g., RGB, Vsync, Hsync, CLK′, etc.) and may transmit the generated gate control signal GCS to the gate driver 1200. The gate control signal GCS may include a signal that directs a scanning start, a signal that controls an output cycle of a gate-on voltage, and a signal that adjusts a duration time of a gate-on voltage.

The gate driver 1200 may drive gate lines GL1 to GLn so that the data stream DATA stream' is sequentially output to the display panel 1400 in response to the gate control signal GCS.

The source driver 1300 may include a clock and data recovery circuit 1320 that checks an error of the data stream DATA stream' received from the timing controller 1100 and recovers the error. The clock and data recovery circuit 1320 may include the delay locked loop 100. The clock and data recovery circuit 1320 may prevent or reduce a likelihood of a glitch of a clock signal, which is output from the delay locked loop 100. The clock and data recovery circuit 1320 may improve quality of output data by providing a stable clock not including a glitch to the inside of the display device 1000. The source driver 1300 may output a gray scale voltage corresponding to the received data stream DATA stream' to the display panel 1400 through source lines SL1 to SLm.

The display panel 1400 may include pixels PX arranged in a place where the gate lines (GL1 to GLn cross the source lines SL1 to SLm. The display panel 1400 may be a display panel, such as an organic light-emitting diode (OLED), a liquid crystal display (LCD) panel, an eleetrophoretic display panel, an electrowetting display panel, a plasma display panel (PDP), etc. However, the display panel 1400 is not limited to the aforementioned embodiments and may be implemented in various ways according to other embodiments of the inventive concept.

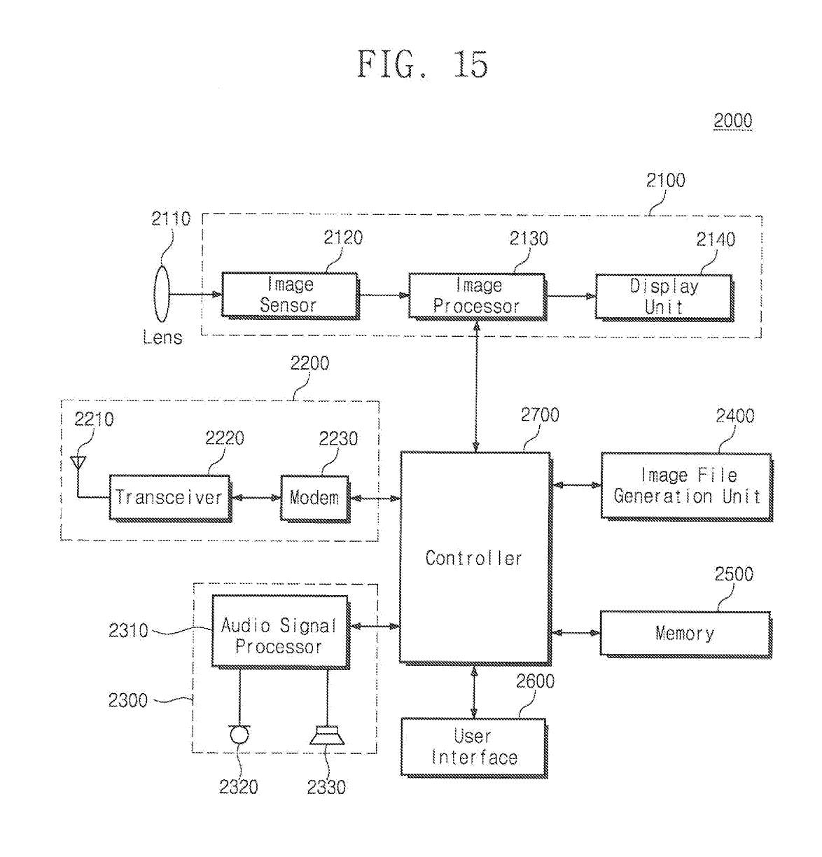

FIG. 15 is a block diagram illustrating a user system including a delay locked loop 100 according to example embodiments of the inventive concept. Referring to FIGS. 1 and 15, a user system 2000 may include an image processing unit 2100, a wireless transmission and reception unit 2200, an audio processing unit 2300, an image file generation unit 2400, a memory 2500, a user interface 2600, and a controller 2700.

The image processing unit 2100 includes a lens 2110, an image sensor 2120, an image processor 2130, and a display unit 2140. The wireless transmission and reception unit 2200 includes an antenna 2210, a transceiver 2220, and a modem 2230. The audio processing unit 2300 includes an audio processor 2310, a mike 2320, and a speaker 2330.

The memory 2500 may be provided in the form of a memory module DIMM, a memory card (MMC, eMMC, SD, micro SD), etc. The controller 2700 may include the image processor 2130 or the modem 2230.

At least one of the image processor 2130, the transceiver 2220, the memory 2500, and the controller 2700 may include the delay locked loop 100 described with reference to FIGS. 1 through 14. Thus, at least one of the image processor 2130, the transceiver 2220, the memory 2500, and the controller 2700 may improve quality of output data by providing a stable clock not including a glitch to the inside of the user system 2000.

A delay locked loop according to example embodiments of the inventive concept may generate a high speed output signal with improved accuracy by preventing or reducing a likelihood of a glitch of an internal clock signal.

While the inventive concept has been particularly shown and described with reference to embodiments thereof, it will be understood that various changes in form and details may be made therein without departing from the scope of the following claims.

What is claimed is:

1. A delay locked loop comprising:
a first delay line configured to generate a first delay clock signal delayed by a first time as compared with an input clock signal by delaying the input clock signal through a plurality of logic gates and a second delay clock signal delayed by a second time as compared with the input clock signal by delaying the input clock signal through the plurality of logic gates; and
a second delay line configured to output an output clock signal based on one of a first signal having a first phase of the first delay clock signal, a second signal having a second phase of the second delay clock signal, and an interpolation signal having a third phase between the first phase and the second phase,
wherein the, second delay line is further configured to transition from outputting the output clock signal based on the first signal to outputting the output clock signal based on the second signal by outputting the output clock signal based on the interpolation signal before outputting the output clock signal based on the second signal; and
wherein the third phase is adjusted in stages by a reference value from the first phase to the second phase while the second delay line outputs the output clock signal based on the interpolation signal.

2. The delay locked loop of claim 1, wherein the second delay line comprises:
a first control circuit comprising a plurality of first control cells for generating the first signal based on the first delay clock signal;
a second control circuit including a plurality of second control cells for generating the second signal based on the second delay clock signal; and
an inverter configured to generate the output clock signal by inverting one of the first signal, the second signal, and the interpolation signal based on the first signal and the second signal.

3. The delay locked loop of claim 2, wherein the plurality of first control cells complementarily operates relative to the plurality of second control cells.

4. The delay locked loop of claim 2, wherein when where the first control cells are activated and the second control cells are inactivated, the output clock signal is generated based on the first phase of the first signal,
wherein when the first control cells are sequentially inactivated and the second control cells are sequentially activated, the output clock signal is generated based on the third phase of the interpolation signal, and
wherein when the first control cells are inactivated and the second control cells are activated, the output clock signal is generated based on the second phase of the second signal.

5. The delay locked loop of claim 2, wherein the delay locked loop further comprises:
a delay replica circuit configured to generate a feedback clock signal by delaying the output clock signal;
a phase detector configured to compare a phase of the input clock signal with a phase of the feedback clock signal and to generate a phase detection signal as a comparison result; and
a delay controller configured to generate a delay code based on the phase detection signal.

6. The delay locked loop of claim 5, wherein the delay controller is configured to generate:
a first delay code output to the first delay line, to control an operation of the plurality of logic gates of the first delay line based on the phase detection signal; and
a second delay code output to the second delay line, to generate the output clock signal based on one of the first signal, the second signal, and the interpolation signal based on the first delay code.

7. The delay locked loop of claim 6, wherein the delay locked loop further comprises:
a first delay code generator configured to generate a first thermometer code and a second thermometer code by decoding the first delay code; and
a second delay code generator configured to generate a third thermometer code and a fourth thermometer code by decoding the second delay code.

8. The delay locked loop of claim 7, wherein an activation or an inactivation of each of the first control cells and the second control cells is controlled based on the third thermometer code and the fourth thermometer code.

9. The delay locked loop of claim 7, wherein each of the first control cells comprises:
first and second transistors, a gate terminal of each of the first and second transistors configured to receive the second delay clock signal and one end of each of the first and second transistors is connected to each other;
a third transistor having one end connected to an other end of the first transistor, an other end of the third transistor configured to receive a power supply voltage, and a gate terminal of the third transistor configured to receive the third thermometer code; and
a fourth transistor having one end connected to an other end of the second transistor, an other end of the fourth transistor connected to a ground terminal, and a gate terminal of the fourth transistor configured to receive the fourth thermometer code.

10. The delay locked loop of claim 7, wherein each o f the second control cells comprises:
first and second transistors, a gate terminal of each of the first and second transistors configured to receive the second delay clock signal and one end of each of the first and second transistors is connected to each other;
a third transistor having one end connected to an other end of the first transistor, an other end of the third transistor configured to receive a power supply voltage, and a gate terminal of the third transistor configured to receive the fourth thermometer code; and
a fourth transistor having one end connected to and other end of the second transistor, an other end of the fourth transistor connected to a ground terminal, and a gate terminal of the fourth transistor configured to receive the third thermometer code.

11. The delay locked loop of claim 1, wherein the first delay clock signal is generated through a first number of logic gates among the plurality of logic gates, the second delay clock signal is generated through a second number of logic gates among the plurality of logic gates, and the first number is different from the second number.

12. A delay locked loop comprising:
a first delay line configured to generate a first delay clock signal by delaying an input clock signal through a first number of logic gates among a plurality of logic gates and, a second delay clock signal by delaying the input clock signal through a second number of logic gates among the plurality of logic gates; and
a second delay line configured to output an output clock signal based on one of a first signal having a first phase of the first delay clock signal, a second signal having a second phase of the second delay clock signal, and an interpolation signal having a third phase adjusted in stages by a reference value between the first phase and the second phase,
wherein the first number is different from the second number.

13. The delay locked loop of claim 12, wherein difference between the first number and the second number is two.

14. The delay locked loop of claim 12, wherein the second delay line comprises:
a first control circuit comprising a plurality first control cells for generating the first signal based on the first delay clock signal;
a second control circuit including a plurality second control cells for generating the second signal based on the second delay clock signal; and
an inverter configured to generate the output clock signal by inverting one of the first signal, the second signal, and the interpolation signal based on the first signal and the second signal.

15. The delay locked loop of claim 12, wherein the first delay clock signal is delayed by a first time as compared with the input clock signal and the second delay clock signal is delayed by a second time different from the first time as compared with the input clock signal.

16. A delay locked loop, comprising:
a first delay line configured to generate a first delay clock signal having a first phase and a second delay clock signal having a second phase responsive to an input clock signal; and
a second delay line configured to generate an interpolation signal having a third phase based on the first and second delay clock signals, such that the third phase is sequentially incremented over a plurality of cycles of the input clock signal so as to span a phase range defined by the first phase and the second phase.

17. The delay locked loop of claim 16, wherein the second delay line is further configured to generate an output clock signal based on one of the first delay clock signal, the second delay clock signal, and the interpolation signal.

18. The delay locked loop of claim 17, wherein the second delay line is further configured to transition from generating the output clock signal based on the first delay clock signal to generating the output clock signal based on the second signal by generating the output clock signal based on the interpolation signal before generating the output clock signal based on the second delay clock signal.

19. The delay locked loop of claim 17, wherein the first delay line comprises a plurality of logic gates and is further configured to generate the first delay clock signal by routing the input clock signal through a first number of the plurality of logic gates and is further configured to generate the second delay clock signal by routing the input clock signal through a second number of the plurality of logic gates where the first number is different than the second number.

20. The delay locked loop of claim 17, further comprising;
a delay replica circuit configured to generate a feedback clock signal based on the output clock signal;
a phase detector configured to generate a phase detection signal based on respective phases of the input clock signal and the feedback clock signal; and
a delay controller configured to generate a first and second delay codes based on the phase detection signal;
wherein the first delay line is configured to receive the first delay code and the second delay line is configured to receive the second delay code.
